(19) United States
(12) Patent Application Publication
(10) Pub. No.: US 2026/0096493 A1
(43) Pub. Date: Apr. 2, 2026

(54) SEMICONDUCTOR PACKAGE HAVING FIRST AND SECOND SUBSTRATES CONNECTED TO CONNECTOR ELEMENTS OF A LEADFRAME

(71) Applicant: Infineon Technologies Austria AG, Villach (AT)

(72) Inventors: Balehithlu Manjappaiah Upendra, Singapore (SG); Raymund Nonato Jotea Concepcion, Bulacan (PH); Kye Ryung Kim, Yeonsu-gu, Incheon (KR); Kyoung Min Song, Cheonan-si, Chungcheongnam-do (KR); Eprel Gabato, Cheonan-si, Chungcheongnam-do (KR); Chiew Men Peong, Johor (MY); Yong Ha Jung, Incheon, Incheon, Chungcheongnam-do (KR)

(21) Appl. No.: 19/339,811

(22) Filed: Sep. 25, 2025

(30) Foreign Application Priority Data
Sep. 30, 2024 (DE) 102024128307.6

(51) Int. Cl. H01L 23/498; H01L 21/48; H01L 21/56; H01L 23/00; H01L 23/31; H01L 23/373; H10D 80/00

(52) U.S. Cl. CPC H10W 90/401; H10D 80/00; H10W 40/255; H10W 74/016; H10W 74/111; H10W 99/00; H10W 72/5453; H10W 72/884; H10W 90/734; H10W 90/754; H10W 90/755

(57) ABSTRACT

A semiconductor package includes: a plurality of leads including first leads and second leads; a first substrate connected to the first leads; a second substrate connected to one or more connector elements; and an encapsulant covering the first substrate, the second substrate and inner portions of the first leads and the second leads.

### TECHNICAL FIELD

The present disclosure is related to a semiconductor package and a method for fabricating the same.

### BACKGROUND

In the field of semiconductor transistor packages, there are some in which two substrates are arranged within a common package containing a lead frame. Semiconductor transistor dies are applied to a first substrate of these substrates and at least one semiconductor driver die is applied to a second substrate. The contact terminals of the semiconductor dies and the driver dies are connected to the leads of the lead frame with bonding wires.

Recently, however, it has become apparent that the manufacturing processes currently used for these semiconductor packages are rather complex and therefore costly. In particular, the way in which the substrates are currently connected to the lead frame has proven to be very complex.

For these and other reasons there is a need for the present disclosure.

### SUMMARY

A first aspect of the present disclosure is related to a semiconductor package, comprising a plurality of leads comprising first leads and second leads, a first substrate connected to the first leads, a second substrate connected to one or more connector elements, and an encapsulant covering the first substrate, the second substrate and inner portions of the first leads and the second leads.

One or both of the first and second substrates are one or more of a printed circuit board, direct copper bonded substrate, a direct aluminum bonded substrate, an active metal brazing substrate, an insulated metal substrate, a ceramic layer, or a silicon layer.

The semiconductor package according to the first aspect may further comprise solder layers between the first substrate and the first leads and solder layers between the second substrate and the connector elements.

The first substrate is intended to have one or more semiconductor transistors applied thereto and the second substrate is intended to have one or more semiconductor driver dies applied thereto.

A second aspect of the present disclosure is related to a method for fabricating a semiconductor package, the method comprising providing a leadframe comprising a frame, a plurality of leads connected to the frame and comprising first leads and second leads, and one or more connector elements connected to the frame, connecting a first substrate to the first leads, connecting a second substrate to the connector elements, attaching one or more semiconductor transistor dies to the first substrate, attaching a driver die to the second substrate, connecting the semiconductor transistor die by bond wires to the leads of the leadframe and to the driver die, applying an encapsulant to cover the first substrate, the second substrate and inner portions of the leads of the leadframe, and removing the frame of the leadframe.

Both of the first and second substrates can be connected to the first leads and to the connector elements of the leadframe by applying a solder layer on one or both of the respective connection partners, bringing them in contact with each other and then performing a solder reflow process.

In particular a single simultaneous solder reflow process can be carried out for connecting the first substrate to the first leads and the second substrate to the connector elements.

Alternatively, both of the first and second substrates can be connected to the first leads and to the connector elements of the leadframe by laser welding one or both of the respective connection partners. In particular, these connections can be performed in a single pass of a welding tool.

The proposal in this disclosure will not only strengthen the bonds between these connections but also greatly improve line flexibility as it enables the production line to operate with a unified configuration rather than segregating DCB packages from leadframe packages.

Implementation of this disclosure can streamline the production process, enhance UPH (units per hour) and boost the product quality substantially by increasing bond strength up to 15 times, effectively eliminating the risk of wire damage defects such as wire short and wire sagging.

### BRIEF DESCRIPTION OF THE DRAWINGS

The accompanying drawings are included to provide a further understanding of embodiments and are incorporated in and constitute a part of this specification. The drawings illustrate embodiments and together with the description serve to explain principles of embodiments. Other embodiments and many of the intended advantages of embodiments will be readily appreciated as they become better understood by reference to the following detailed description.

The elements of the drawings are not necessarily to scale relative to each other. Like reference numerals designate corresponding similar parts.

FIG. 1 shows a perspective view on an example of a leadframe.

FIG. 2 shows a perspective view on an example of a semiconductor package without encapsulant in a stage after removing the frame of the leadframe.

FIG. 3 shows a perspective view on a section of an example of a printed circuit board (PCB).

FIG. 4 shows a perspective view on the semiconductor package of FIG. 2, after applying the encapsulant.

FIG. 5 shows a flow diagram of a method for fabricating a semiconductor package.

### DETAILED DESCRIPTION

In the following detailed description, reference is made to the accompanying drawings, which form a part hereof, and in which is shown by way of illustration specific embodiments in which the disclosure may be practiced. In this regard, directional terminology, such as “top”, “bottom”, “front”, “back”, etc., is used with reference to the orientation of the Figure(s) being described. Because components of embodiments can be positioned in a number of different orientations, the directional terminology is used for purposes of illustration and is in no way limiting. It is to be understood that other embodiments may be utilized and structural or logical changes may be made without departing from the scope of the present disclosure. The following detailed description, therefore, is not to be taken in a limiting sense, and the scope of the present disclosure is defined by the appended claims.

It is to be understood that the features of the various exemplary embodiments described herein may be combined with each other, unless specifically noted otherwise.

As employed in this specification, the terms “bonded”, “attached”, “connected”, “coupled” and/or “electrically connected/electrically coupled” are not meant to mean that the elements or layers must directly be contacted together; intervening elements or layers may be provided between the “bonded”, “attached”, “connected”, “coupled” and/or “electrically connected/electrically coupled” elements, respectively. However, in accordance with the disclosure, the above-mentioned terms may, optionally, also have the specific meaning that the elements or layers are directly contacted together, i.e. that no intervening elements or layers are provided between the “bonded”, “attached”, “connected”, “coupled” and/or “electrically connected/electrically coupled” elements, respectively.

Further, the word “over” used with regard to a part, element or material layer formed or located “over” a surface may be used herein to mean that the part, element or material layer be located (e.g. placed, formed, deposited, etc.) “indirectly on” the implied surface with one or more additional parts, elements or layers being arranged between the implied surface and the part, element or material layer. However, the word “over” used with regard to a part, element or material layer formed or located “over” a surface may, optionally, also have the specific meaning that the part, element or material layer be located (e.g. placed, formed, deposited, etc.) “directly on”, e.g. in direct contact with, the implied surface.

The examples of a semiconductor package and a method for fabricating a semiconductor package may use various types of transistor devices. The examples may also use horizontal or vertical transistor devices wherein those structures may be provided in a form in which all contact elements of the transistor device are provided on one of the main faces of the semiconductor die (horizontal transistor structures) or in a form in which at least one electrical contact element is arranged on a first main face of the semiconductor die and at least one other electrical contact element is arranged on a second main face opposite to the main face of the semiconductor die (vertical transistor structures) like, for example, MOS transistor structures or IGBT (Insulated Gate Bipolar Transistor) structures. Insofar as the transistor dies are configured as power transistor dies, the examples of a semiconductor package disclosed further below can be classified as so-called intelligent power modules (IPM).

According to an embodiment of the semiconductor package, the semiconductor transistor die is a semiconductor power transistor die. Here, the term “power semiconductor transistor die” may refer to a semiconductor die providing at least one of high voltage blocking or high current-carrying capabilities. A power semiconductor die may be configured for high currents having a maximum current value of a few Amperes, such as e.g. 10 A, 250 A, 600 A, 1000 A, or a maximum current value of up to or even exceeding 1000 A. Similarly, voltages associated with such current values may have values of a few Volts to a few tens or hundreds or even thousands of Volts.

The examples of a semiconductor package may comprise an encapsulant or encapsulating material having the semiconductor transistor die and the semiconductor driver die embedded therein. The encapsulating material can be any electrically insulating material like, for example, any kind of molding material, any kind of resin material, or any kind of epoxy material. The encapsulating material can also be a polymer material, a polyimide material, a thermoplast material, a silicone material, a ceramic material, and a glass material. The encapsulating material may also comprise any of the above-mentioned materials and further include filler materials embedded therein like, for example, thermally conductive increments like thermally conductive particles like, for example, made of AlO, BNi, AlNi, SiN, diamond, or any other thermally conductive particles.

The examples of a semiconductor package may further comprise a plurality of passive devices like, for example, resistors, capacitors, inductors and the like. Also an NTC (negative temperature coefficient) temperature sensor may be provided. These passive devices can be connected to the panel, for example, spatially near to the driver die.

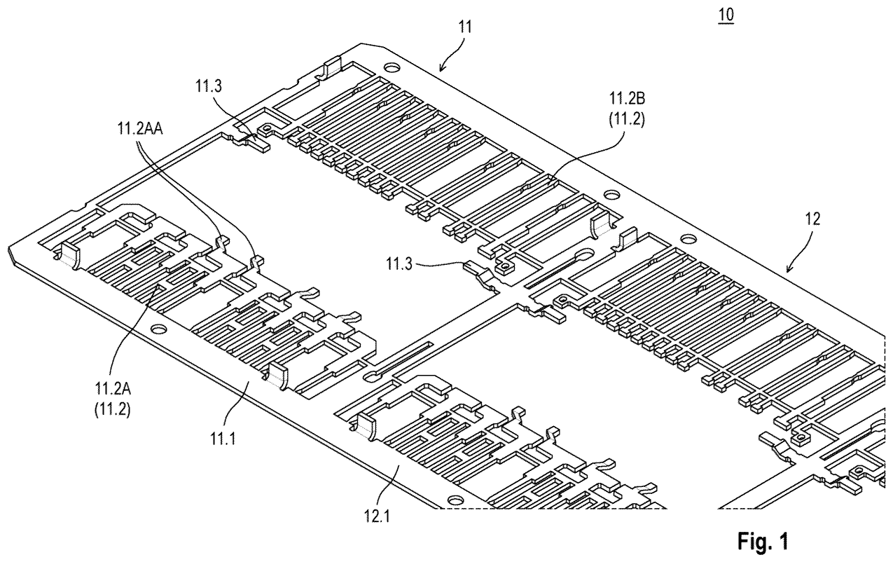

FIG. 1 shows a perspective view of an example of a leadframe 10.

The leadframe 10 of FIG. 1 comprises a first leadframe 11 comprising a frame 11.1 and a plurality of leads 11.2 connected with the frame 11.1. The plurality of leads 11.2 comprise first leads 11.2A and second leads 11.2B. Some of the first leads 11.2A have inner ends that are designed as first connector elements 11.2AA and extend into the interior of the first leadframe 11. The first leadframe further comprises second connector elements 11.3 which are connected with the frame 11.1 and likewise extend into the interior of the first leadframe 11.

The example of the leadframe 10 as shown in FIG. 1 is one which comprises a second leadframe 12 wherein the first and second leadframe 11 and 12 are connected via their frames 11.1 and 12.1. In this way a plurality of single leadframe can be connected with each other.

The leadframe 10 can be made of copper or a copper alloy. According to an example thereof, the leadframe 10 comprises a coating of Ni, Ni/NiP, Ni/NiNiP, or any other suitable coating.

The interior of the first leadframe 11 is dimensioned so that a first substrate and a second substrate can be accommodated therein and connected to and held by the first and second connector elements 11.2AA and 11.3.

The first connector elements 11.2AA are arranged side-by-side and extend from there into the interior of the first lead frame 11. The second connector elements 11.3 are connected to the frame 11.1 at opposite positions of the frame 11.1 and also extend from there into the interior of the first lead frame 11. The second connector elements 11.3 are formed integral with the frame 11.1.

In an embodiment described further below, a direct copper bond (DCB) is provided as the first substrate, which is connected to the first connector elements 11.2AA. The second substrate is a printed circuit board (PCB), which is connected to the second connector elements 11.3.

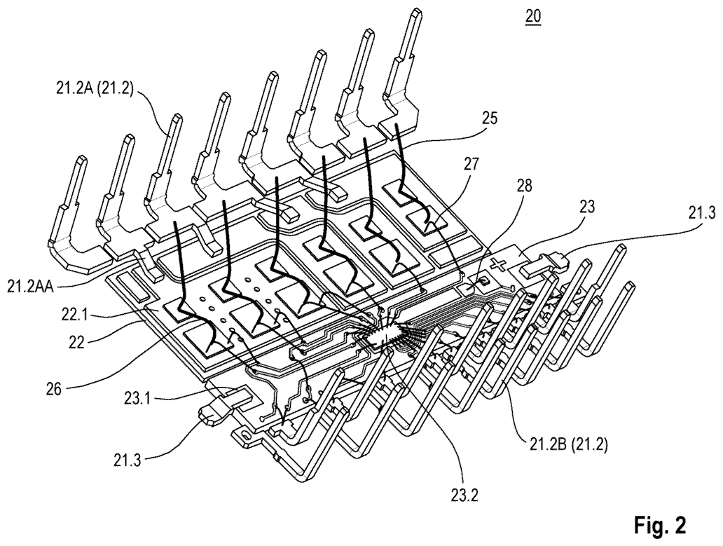

FIG. 2 shows a perspective view on an example of a semiconductor package 20 without encapsulant in a stage after removing the frame of the leadframe.

The semiconductor package 20 as shown in FIG. 2 comprises leads 21.2, in particular first leads 21.2A and second leads 21.2B both resulting, for example, from the first leads 11.2A and the second leads 11.2B of the first leadframe 11 of the leadframe 10 as shown in FIG. 1. First connector elements 21.2AA result from the first connector elements 11.2AA and second connector elements 21.3 result from the second connector elements 11.3 as shown in FIG. 1.

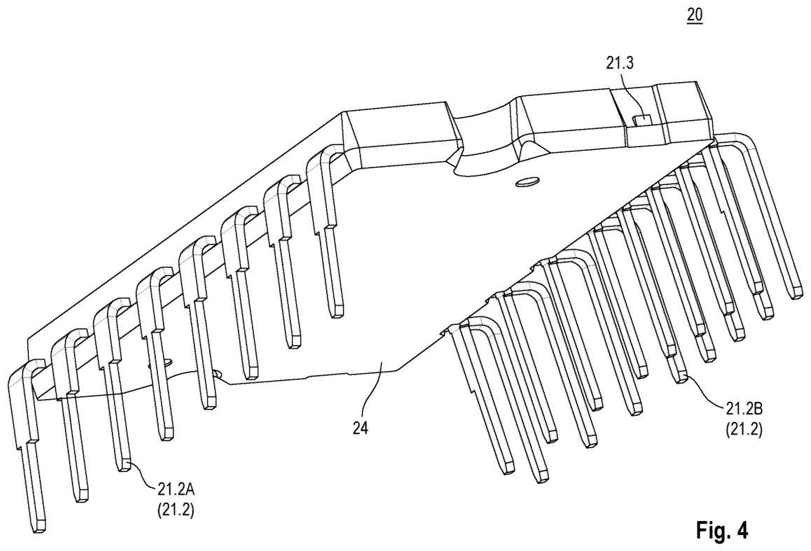

The semiconductor package 20 further comprises a direct copper bond (DCB) substrate 22 connected to the first connector elements 21.2AA and a printed circuit board (PCB) 23 connected to the second connector elements 11.3. The semiconductor package 20 furthermore comprises an encapsulant which is omitted here and covers the first substrate, the second substrate and inner portions of the leads 21.2 (see FIG. 4).

The DCB 22 contains a central ceramic layer with copper layers on both surfaces. The upper copper layer is divided into individual copper layer sectors 22.1. On each one of these copper layer sectors 22.1 a semiconductor transistor die and a semiconductor diode die connected in parallel with the semiconductor transistor die are applied. The semiconductor transistor die can, for example, be an IGBT die having a drain contact on its back surface and source contact, gate contact and source/sense contact on its front surface. The semiconductor dies may be connected to the copper layer sectors 22.1 by a number of different methods including soft solder and solder paste, preform solder, sintering or diffusion soldering.

As shown in FIG. 2, the first leads 21.2A and the second leads 21.2B have been bent at right angles. The first leads 21.2A are connected with their first connector elements 21.2AA by first surface bonds to the copper layer sectors 22.1 of the DCB 22 to which copper layer sectors 22.1 the semiconductor transistor dies are applied. The second connector elements 21.3 are connected by second surface bonds to copper layers 23.1 disposed on the PCB 23. The first and second surface bonds may be fabricated by preform soldering which means that they take the form of a thin, planar solder layer placed between the respective connection partners prior to soldering via a reflow solder process.

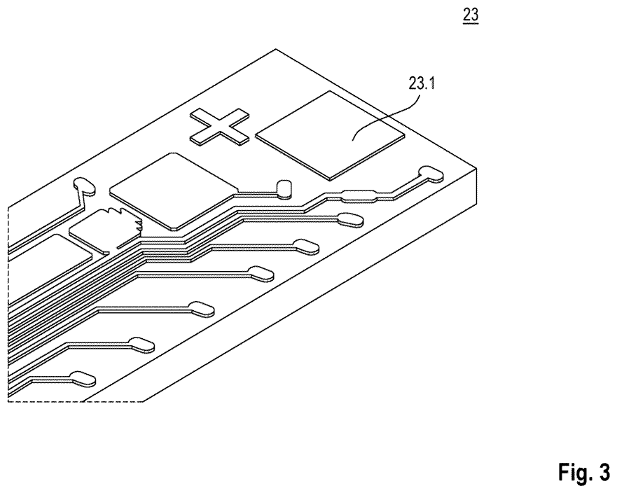

FIG. 3 shows a perspective view on a section of an example of a printed circuit board (PCB) 23.

The PCB 23 as shown in FIG. 3 comprises a circuitry containing a driver die (not shown here). On each one of the short sides of the PCB 23, of which only one is shown here, the PCB 23 comprises a copper layer 23.1. These copper layers 23.1 serve to be connected to the second connector elements 11.3 of the frame 11.1 of the first lead frame 11 shown in FIG. 1. These connections have no electrical functionality, but only serve to hold the PCB 23 by the frame 11 during the fabrication process.

The preform soldering results in a strong bond strength and, in the case of the connection between the first leads 21.2A and the copper layer sections 22.1, increased current carrying capacity and improved thermal performance.

Both the connections between the first leads 11.2A and the copper layer sectors 22.1 and the connections between the connector elements 21.3 and the copper layers 23.1 can also be produced by laser welding instead of preform soldering. Also other beam welding methods are possible as, for example, electron beam welding. In such a case the result will be substance-to-substance bonds with no bonding material layer between the respective connection partners. These connections would also form strong bonds, also due to the direct Cu—Cu bond.

As can also be seen in FIG. 2, all of the first conductors 11.2A are connected to one of the copper layer sectors 22.1. Most of the first leads 21.2A are also connected by first bonding wires 25 to an upper contact terminal of one of the semiconductor diode dies. Second bond wires 26 are then connected between this contact terminal and the source contact terminal of the associated semiconductor transistor dies, so that both devices are electrically connected in parallel.

As FIG. 2 also shows, a circuitry containing a semiconductor driver die 23.2 is arranged on the PCB 23. The circuitry is connected to third bonding wires 27 that lead to the gate and source/sense contacts of the semiconductor transistor dies. Second leads 21.2B are connected to the PCB circuitry via further bonding wires 28.

FIG. 4 shows a perspective view on the semiconductor package 20 of FIG. 2, after applying an encapsulant.

The semiconductor package 20 as shown in FIG. 4 is in principle the same as that shown and described in connection with FIG. 2. The semiconductor package 20 now comprises in addition an encapsulant 24 which covers the DCB, the PCB, and inner portions of the leads 21.2. The outer portions of the first leads 21.2A and the second leads 21.2B, which are bent at right angles, are not covered by the encapsulant. Also shown within the circular outline is the outer outwardly exposed end of one of the two first connector elements 21.3. The other of the two first connector elements 21.3 is also exposed outwardly on the opposite side of the semiconductor package 20.

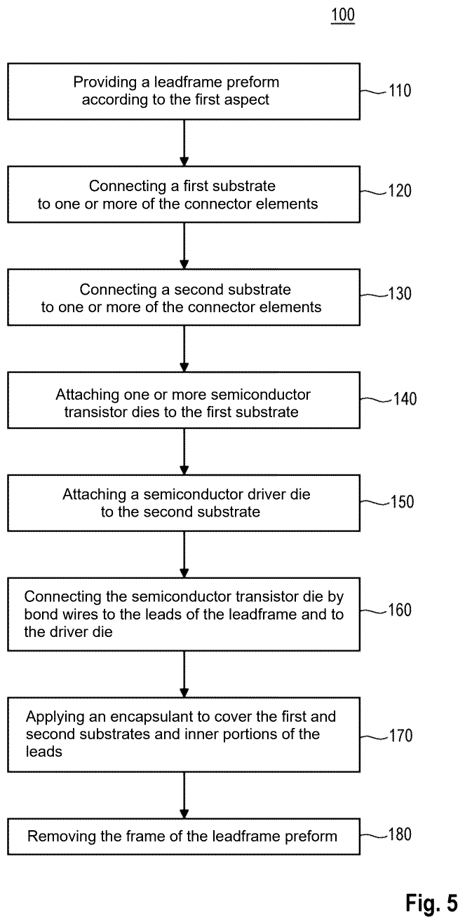

FIG. 5 shows a flow diagram of a method for fabricating a semiconductor package.

The method 100 as shown in FIG. 5 comprises: providing (110) a leadframe comprising a frame, a plurality of leads connected to the frame and comprising first leads and second leads, and one or more connector elements connected to the frame; connecting (120) a first substrate to the first leads; connecting (130) a second substrate to the connector elements; attaching (140) one or more semiconductor transistor dies to the first substrate; attaching (150) a driver die to the second substrate; connecting (160) the semiconductor transistor die by bond wires to the leads of the leadframe and to the driver die; applying (170) an encapsulant to cover the first substrate, the second substrate and inner portions of the leads of the leadframe; and removing (180) the frame of the leadframe.

Thereafter the outer portions of the leads 21.2 can be bent at right angles to arrive at a semiconductor package 20 as shown in FIG. 4.

According to an embodiment of the method, the first substrate comprises a direct copper bond (DCB) and the second substrate comprise a printed circuit board (PCB).

According to an embodiment of the method, the first leads comprise integral inner end portions formed as second connector elements and the first substrate is connected to the second connector elements.

According to an embodiment of the method connecting the first substrate to the first leads comprises applying a solder layer on one or both of the first substrate and the first leads, bringing the first substrate and the first leads in contact with each other and performing a solder reflow process for fastening the first substrate to the first leads.

According to an embodiment of the method, connecting the second substrate to the connector elements comprises applying a solder layer on one or both of the second substrate and the connector elements, bringing the second substrate and the connector elements in contact with each other and performing a solder reflow process for fasting the second substrate to the connector elements.

According to an embodiment of the method, the method further comprises a single simultaneous solder reflow process for connecting the first substrate to the first leads and the second substrate to the connector elements.

In other words, it becomes possible herewith to connect the first leads to the DCB and the connector elements to the PCB in a single process. The thin solder preforms are preferably applied to both first and second substrates during initial processing, and then once the substrates are placed within the frame and the frame connectors placed on the preform, all bonds are processed during a single reflow step. Thus both substrates, and the PCB in particular, are securely held in position during the molding process which follows. In addition, the semiconductor dies could also be permanently soldered to the DCB during the same reflow process if they are mechanically but not electrically connected to the DCB during connection step 140.

According to another embodiment of the method, the method comprises laser welding of both the first leads to the DCB and the connector elements to the PCB during a single pass of a welding tool, such that these connections are made during a single step in the manufacturing process.

It should be noted that the method can be combined with any one of the structural features which were shown and described above in connection with the leadframe or the semiconductor package.

In addition, while a particular feature or aspect of an embodiment of the disclosure may have been disclosed with respect to only one of several implementations, such feature or aspect may be combined with one or more other features or aspects of the other implementations as may be desired and advantageous for any given or particular application. Furthermore, to the extent that the terms “include”, “have”, “with”, or other variants thereof are used in either the detailed description or the claims, such terms are intended to be inclusive in a manner similar to the term “comprise”. Furthermore, it should be understood that embodiments of the disclosure may be implemented in discrete circuits, partially integrated circuits or fully integrated circuits or programming means. Also, the term “exemplary” is merely meant as an example, rather than the best or optimal. It is also to be appreciated that features and/or elements depicted herein are illustrated with particular dimensions relative to one another for purposes of simplicity and ease of understanding, and that actual dimensions may differ substantially from that illustrated herein.

Although specific embodiments have been illustrated and described herein, it will be appreciated by those of ordinary skill in the art that a variety of alternate and/or equivalent implementations may be substituted for the specific embodiments shown and described without departing from the scope of the present disclosure. This application is intended to cover any adaptations or variations of the specific embodiments discussed herein. Therefore, it is intended that this disclosure be limited only by the claims and the equivalents thereof.

What is claimed is:

1. A semiconductor package, comprising:
a plurality of leads comprising first leads and second leads;
a first substrate directly connected to the first leads via first surface bonds;
a second substrate connected to the second leads via a plurality of bonding wires;
an encapsulant covering the first substrate, the second substrate and inner portions of the first leads and the second leads; and
one or more connector elements covered by the encapsulant, each connector element being directly connected to the second substrate via a second surface bond identical to the first surface bonds.

2. The semiconductor package of claim 1, wherein the first substrate is one or more of a direct copper bonded substrate, a direct aluminum bonded substrate, an active metal brazing substrate, an insulated metal substrate, a ceramic layer, or a silicon layer.

3. The semiconductor package of claim 1, wherein the second substrate is a printed circuit board.

4. The semiconductor package of claim 1, wherein the first and second surface bonds comprise solder layers.

5. The semiconductor package of claim 1, wherein the first and second surface bonds comprise welded connections.

6. The semiconductor package of claim 1, further comprising:
one or more semiconductor transistor dies disposed on the first substrate.

7. The semiconductor package of claim 6, wherein the one or more semiconductor transistor dies comprise(s) one or more of a vertical semiconductor transistor die, a semiconductor power transistor die, an IGBT die, a MOSFET die, a CoolMOS die, a wide band gap semiconductor transistor die, in particular a SiC transistor die or a GaN transistor die.

8. The semiconductor package of claim 6, further comprising:
a semiconductor driver die disposed on the second substrate.

9. The semiconductor package of claim 8, wherein the one or more semiconductor transistor die(s) is/are connected by bond wires to the driver die.

10. A method for fabricating a semiconductor package, the method comprising:
providing a leadframe comprising a frame, a plurality of leads connected to the frame and comprising first leads and second leads, and one or more connector elements connected to the frame;
connecting a first substrate to the first leads via first surface bonds;
connecting a second substrate to the connector elements via second surface bonds identical to the first surface bonds;
attaching one or more semiconductor transistor dies to the first substrate;
attaching a driver die to the second substrate;
connecting the semiconductor transistor die by bond wires to the driver die;
connecting the second substrate by bond wires to the second leads;
applying an encapsulant to cover the first substrate, the second substrate and inner portions of the leads and connector elements of the leadframe; and
removing the frame of the leadframe.

11. The method of claim 10, wherein connecting the first substrate to the first leads comprises:
applying a solder layer on one or both of the first substrate and the first leads;
bringing the first substrate and the first leads in contact with each other; and
performing a solder reflow process.

12. The method of claim 10, wherein connecting the second substrate to the connector elements comprises:
applying a solder layer on one or both of the second substrate and the connector elements;
bringing the second substrate and the connector elements in contact with each other; and
performing a solder reflow process.

13. The method of claim 10, wherein connecting the first substrate to the first leads and the second substrate to the connector elements comprises a single simultaneous solder reflow process.

14. The method of claim 10, wherein connecting the first substrate to the first leads and the second substrate to the connector elements comprises laser welding.

15. The method of claim 14, wherein connecting the first substrate to the first leads and the second substrate to the connector elements comprises a single pass with a laser welding tool.

16. The method of claim 10, wherein the semiconductor transistor die comprises one or more of a vertical semiconductor transistor die, a semiconductor power transistor die, an IGBT die, a MOSFET die, a CoolMOS die, a wide band gap semiconductor transistor die, in particular a SiC transistor die or a GaN transistor die.
